(19) United States
(12) Patent Application Publication
(10) Pub. No.: US 2006/0081936 A1
(43) Pub. Date: Apr. 20, 2006

(54) Semiconductor device for low power operation

(76) Inventors: Jae-Joon Kim, Yorktown Heights, NY (US); Kaushik Roy, West Lafayette, IN (US)

Correspondence Address: BARNES & THORNBURG, 11 SOUTH MERIDIAN, INDIANAPOLIS, IN, 46204, US

(21) Appl. No.: 11/229,226

(22) Filed: Sep. 16, 2005

Related U.S. Application Data
(60) Provisional application No. 60/614,157, filed on Sep. 28, 2004.

(51) Int. Cl. H01L 29/76

(52) U.S. Cl. 257/365

(57) ABSTRACT

A semiconductor device for low power operation includes a channel region having a channel length greater than a standard minimum channel length. The voltage supply of the device is less than the threshold voltage of the device. A gate terminal of the device may have a raised height relative to a source and drain region of the device. In one embodiment, the semiconductor device is a double gate metal-oxide field effect transistor.

This patent application claims priority to and the benefit of U.S. Provisional Patent Application Serial No. 60/614,157 entitled “Semiconductor Device For Low Power Operation” which was filed on Sep. 28, 2004, the entirety of which is expressly incorporated herein by reference.

### BACKGROUND OF THE INVENTION

The present disclosure relates generally to semiconductor devices, and more particularly, to semiconductor devices for low power operation.

The steady scaling down of semiconductor devices has been the driving force of the realization of high-performance Very Large Scale Integration (VLSI) systems. In many applications, the primary design consideration is the high-speed performance of the scaled devices. However, such high-speed performance may not be the only consideration in some particular applications such as portable wireless devices and medical devices. In such applications, low power consumption may be an additional consideration.

In low power consumption applications, a lower supply voltage may be used to achieve a better power-delay product with a slower, but generally acceptable, operation speed. One particular low voltage circuit design is the sub-threshold circuit which uses a supply voltage (Vdd) that is lower than the threshold voltage (Vth) of the semiconductor device such as a transistor (i.e., an amount of voltage required to switch the semiconductor device from a blocking state to a conducting state). In many sub-threshold circuit designs, typical semiconductor devices are used. Such typical semiconductor devices, however, are designed for operation in strong inversion mode and, accordingly, may not provide desirable results when used in sub-threshold applications.

### SUMMARY OF THE INVENTION

The present invention comprises one or more of the features recited in the appended claims and/or the following features which, alone or in any combination, may comprise patentable subject matter:

A semiconductor device for low power operation is provided. The semiconductor device may be fabricated according to a predetermined technology node process. The predetermined technology node process may define a minimum channel length. The device may be a transistor or other semiconductor device. For example, the device may be a double gate metal-oxide semiconductor field effect transistor. The device may have a source region and/or a drain region defined on or in a substrate. A channel region may be defined between the source and drain regions. The channel region may have a channel length greater than a minimum channel length as defined by a technology node process. The channel length may be determined based on a time delay associated with the channel length. For example, the channel length may be determined based on a minimum time delay associated with the channel length. Additionally or alternatively, the channel length may be determined based on a minimum threshold slope associated with the channel length. The device may also have one or more gate terminals. One or more of the gate terminals may be raised above the source and drain regions. The source and drain regions may have top surfaces coplanar with a top surface of the substrate. The device may be used in a sub-threshold operation circuit. In such a circuit, the device may have a supply voltage that is less than the threshold voltage of the device.

A method of fabricating a device on a substrate having a top surface is also provided. The method may include processing the device according to a predetermined technology node process. The predetermined technology node process may define a minimum channel length. The method may include establishing a source region and/or drain region on the substrate. The source and/or drain regions may have top surfaces substantially coplanar with the top surface of the substrate. The method may further include defining a channel region between the source and drain regions. The channel region may have a channel length greater than the minimum channel length. The channel length of the channel region may be determined based on a time delay, for example a minimum time delay, associated with the channel length. Additionally or alternatively, the channel length may be determined based on a minimum threshold slope associated with the channel length. The method may also include establishing first gate region over the channel region. The first gate region may have a height greater than a height of the source and drain regions. The method may further include establishing a second gate region over the channel region. The second gate region may have a height greater than a height of the source and drain regions. The source and/or drain regions may be established via any semiconductor processing method. For example, the source and/or drain regions may be established via ion implantation.

The above and other features of the present disclosure, which alone or in any combination may comprise patentable subject matter, will become apparent from the following description and the attached drawings.

### BRIEF DESCRIPTION OF THE DRAWINGS

The detailed description particularly refers to the following figures, in which:

FIG. 1 is a graph illustrating the sensitivity of the operating current (Iₒₙ) of a Double Gate (DG) MOSFET to variation of channel length (L_{ch}), gate oxide thickness (Tₒₓ), and silicon bony thickness (Tₛᵢ);

FIG. 2 is a graph illustrating the inverter time delay versus the channel length of a DG MOSFET;

FIG. 3 is a graph illustrating the C_{g} and V_{gs} characteristics of a DG MOSFET with different channel lengths;

FIG. 4 is a graph illustrating the Ion and sub-threshold slope versus the channel length of a DG MOSFET;

FIG. 5 is a graph illustrating the dependence of a DG MOSFET current on source/drain resistance;

FIG. 6 is an illustration of a prior art design of a DG MOSFET having raised source and drain regions;

FIG. 7 is an illustration of a DG MOSFET for low power operation having thin source and drain regions; and

FIG. 8 is a schematic of a sub-threshold circuit using a DG MOSFET configured as an inverter.

### DETAILED DESCRIPTION OF THE DRAWINGS

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the disclosure.

One exemplary semiconductor device that may be used for sub-threshold circuit design is the Double Gate Metal-Oxide Semiconductor Field Effect Transistor (DG MOSFET). Due to the improved sub-threshold slope of a DG (fully depleted) MOSFET, such devices are useful in sub-threshold applications. An exemplary sub-threshold circuit 10 is illustrated in FIG. 8. The circuit 10 includes a DG MOSFET 12 configured as an inverter, however, other circuit configurations may be used. Additionally, the circuit 10 may include or otherwise be coupled with other electrical devices to form a larger circuit. As shown in FIG. 8, a supply voltage 14 (i.e., V_{dd}) is coupled to the DG MOSFET 12. The supply voltage, V_{dd}, is configured to be less than the threshold voltage, Vₜₕ, of the DG MOSFET 12. As used herein, the term threshold voltage is intended to refer to an amount of voltage required to switch the semiconductor device (e.g., DG MOSFET 12) from a blocking state to a conducting state. The threshold voltage may be defined as a minimum voltage or a range of voltages. Typically the threshold voltage for a particular semiconductor device is defined and provided by the manufacturer of the semiconductor device. Although the present disclosure is described and illustrated in regard to a DG MOSFET, it is contemplated that the disclosure is applicable to other types of semiconductor devices including, but not limited to, other types of MOSFETs such as multi-gate MOSFETs, other types of transistors such as Bipolar Junction Transistors (BJTs), and other types of semiconductor devices.

One design consideration commonly associated with sub-threshold circuit design is that the threshold voltage, Vₜₕ, of the semiconductor device (e.g., MOSFET) may fluctuate due to process variations. The variability of the semiconductor threshold voltage, Vₜₕ, is a consideration in some applications because the operating current of the device exponentially depends on threshold voltage, Vₜₕ, in the sub-threshold region. That is, as the threshold voltage, Vₜₕ, of the semiconductor device varies, the operating current may vary by a much larger amount.

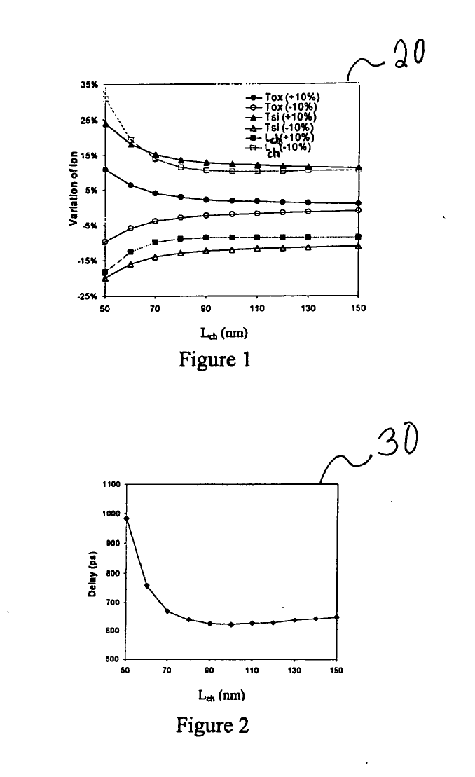

However, as illustrated in and described below in regard to FIGS. 1-4, the tolerance to process variations of a semiconductor device may be increased by increasing the channel length of the semiconductor device (i.e., the distance between diffusion areas of the device such as the distance between a source region and a drain region of a field effect transistor device). That is, a semiconductor device having a channel length longer than the minimum channel length may have an increased tolerance to process variations. The minimum channel length is a standardized or guideline channel length defined for each particular technology node. A technology node is typically designated by a number followed by a metric (e.g., 90 nm technology node, 65 nm technology node, etc.). A technology node defines a minimum geometry spacing, width, radius, or the like that defines the technology. For example, the technology node may define a minimum distance between metal interconnects, a minimum radius of a contact, a minimum space defined between diffusion areas, or the like. Regardless, in any such technology node process which includes a gate defined over a channel, the channel will have a minimum channel length accordingly to the particular technology node. For example, the International Technology Roadmap for Semiconductors (ITRS) has established a guideline for minimum channel length for the 90 nm technology node of about 37 nanometers and a minimum channel length for the 65 nm technology node of about 25 nanometers. Typical semiconductor devices such as typical DG MOSFETS of a particular technology node are designed to have a channel length equal to the minimum channel length specified by the particular technology node.

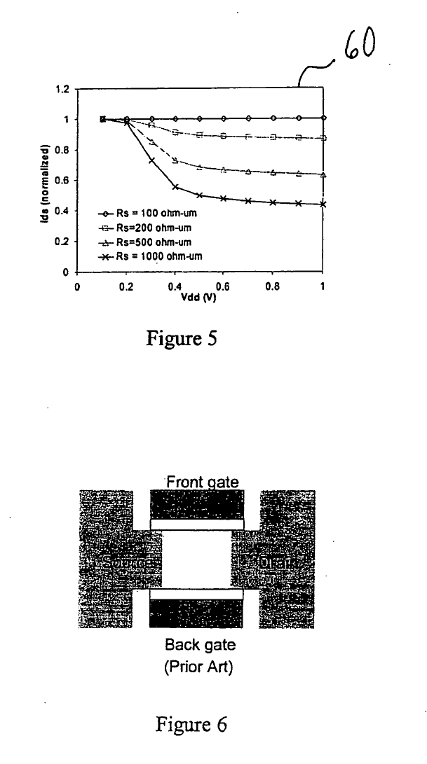

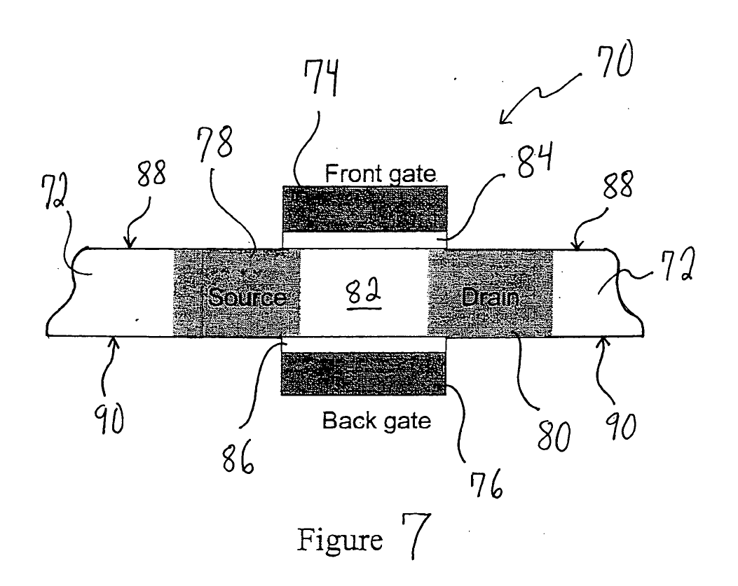

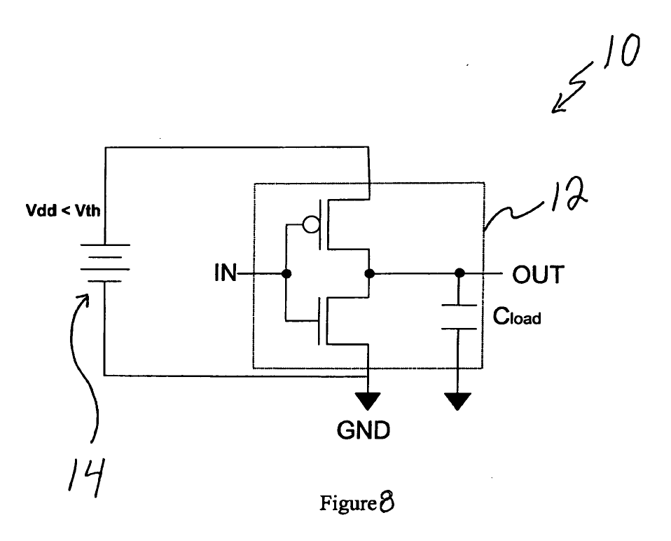

Additionally, as described below in regard to FIGS. 5 and 7, DG MOSFETs for sub-threshold operations do not require the typical raised source/drain structure of conventional sub-threshold devices because the channel resistance is high in sub-threshold operation. Accordingly, the source and drain region structures of the DG MOSFET may be altered for sub-threshold operations to provide improved manufacturability.

As discussed above, because the operating current exponentially depends on the transistor threshold voltage, Vₜₕ, in the sub-threshold region, any fluctuation of the threshold voltage, Vₜₕ, due to process variations may be a consideration for sub-threshold logic design moreso than for super-threshold logic design. A numerical device simulation for DG MOSFETs with symmetrical gates having channel lengths, L_{ch}, of about 50 nanometers (nm), front gate oxide thickness, T_{of}, and back gate oxide thickness, T_{ob}, of about 3 nm (i.e., T_{of}=T_{ob}=Tₒₓ), and with silicon body thickness, Tₛᵢ of about 10 nm was performed. Abrupt source/drain junction and gate-source/drain overlaps of about 40% of the channel length were used for the simulation. The channel length, L_{ch}, was then varied from 50 nm to 150 nm to observe sensitivity to process variations (i.e., +/−10% of the channel length, L_{ch}). Additionally, sensitivity to process variations of the gate oxide thickness, Tₒₓ, and the silicon body thickness, Tₛᵢ, were also observed. The gate overlap length was kept constant for all channel lengths. The gate-to-metal workfunction was adjusted for control of threshold voltage.

Referring now to FIG. 1, a graph 20 illustrating a change in channel length, L_{ch}, versus a change in operating current, Iₒₙ (I_{ds}@V_{dd}=0.2V), for a DG MOSFET is shown. The graph 20 includes the defined or desirable channel length, L_{ch}, on the abscissa axis versus the operating current, Iₒₙ, on the ordinate axis. Variation of +/−10% of the channel length is plotted on the graph 20 with square indicators. The resulting variation of the operating current, Iₒₙ, can be determined for any defined channel length based on the variation of the channel length. For example, a −10% variation of a channel length defined to be 90 nm (i.e., a resulting channel length of about 81 nm) produces a variation in the operating current of about 12%. Variation of +/−10% of the gate oxide thickness, Tₒₓ, is also plotted on the graph 20 with circular indicators. Variation of +/−10% of the silicon body thickness, Tₛᵢ is plotted on the graph 20 with triangular indicators.

As shown in FIG. 1, shorter channel devices (i.e., devices with shorter channel lengths, L_{ch}) are more sensitive to variations in the channel length compared to longer channel devices due to the drain induced barrier lowering (DIBL). That is, as the channel length of the device is increased, the variation of the operating current, Iₒₙ, for a given variation of the channel length (i.e., +/−10%) is reduced. Additionally, as shown in FIG. 1, variation in Tₒₓ causes negligible change in the operating current, Iₒₙ, for longer channel devices. As such, the transistor threshold voltage, Vₜₕ, of longer channel symmetric DG MOSFET devices do not depend on gate oxide thickness, Tₒₓ. Conversely, shorter channel devices experience a relatively large amount of operating current, Iₒₙ, variation due to Tₒₓ variation. Further, as shown in FIG. 1, shorter channel devices are more sensitive to variations in the silicon body thickness, Tₛᵢ, of the semiconductor device compared to longer channel devices. A silicon body thickness, Tₛᵢ, variation of +/−10% causes about a +/−10% variation, respectively, in the operating current, Iₒₙ, for long channel symmetric devices due to the volume inversion effect. The shorter channel devices experience a greater Iₒₙ variation due to two dimensional short channel effects in addition to the volume inversion.

Based on the results of the simulation illustrated in FIG. 1, the suppression of “short channel effects” (i.e., undesirable conditions, such as increased operating current variation, due to the shorter channel lengths) is a consideration for developing semiconductors with reduced transistor threshold voltage, Vₜₕ, fluctuation. As indicated by the graph 20, semiconductor devices having longer channel lengths than the minimum channel length defined by the particular technology node may have reduced “short channel effects” compared to semiconductors having shorter channel lengths such as those semiconductors having channel lengths equal to the minimum channel length. However, in conventional digital super-threshold circuit designs, longer channel devices are not typically used because the longer channel devices are generally slower than shorter channel devices. The speed of the longer channel devices, however, may be increased in sub-threshold operations by matching the off-currents (i.e.m the leakage currents) of the longer channel devices such that the longer channel devices are not substantially slower than shorter channel devices, as described below.

The time delay, t_{d}, in a typical CMOS circuit is proportional to a ratio of the amount of load charge, Q_{load}, and the operating current, Iₒₙ (i.e., t_{d}=Q_{load}/Iₒₙ). In super-threshold operations (i.e., the supply voltage of a semiconductor of the circuit is greater than the defined threshold voltage), assuming the load capacitance is dominated by the gate capacitance, C_{g}, of the load transistor (or other semiconductor device), both the gate capacitance, C_{g}, and the inverse of the operating current, 1/Iₒₙ, are proportional to channel length, L_{ch}. Accordingly, based on the time delay equation provided above, the time delay, t_{d}, is proportional to the square of channel length (L_{ch}²). In shorter channel devices, wherein velocity saturation occurs, the operating current, 1ₒₙ, is a weak function of the channel length, L_{ch}. Therefore, the dependence of time delay, t_{d}, on the channel length, L_{ch}, is mainly determined by the gate capacitance, C_{g}. Accordingly, the time delay, t_{d}, increases linearly with an increase of channel length, L_{ch}, in typical circuits operating in a super-threshold mode.

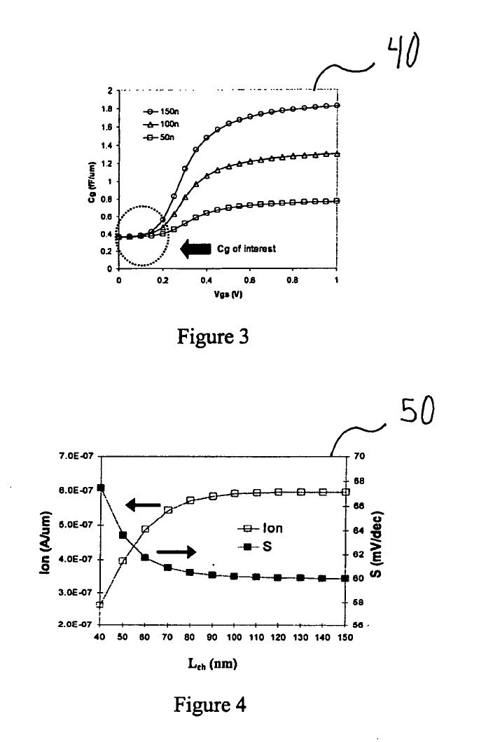

Referring now to FIG. 2, a graph 30 illustrating a change in channel length, L_{ch}, versus a change in delay time (measured in picoseconds) of a DG MOSFET configured as an inverter (see FIG. 7) is shown. The graph 30 includes the channel length, L_{ch}, on the abscissa axis versus the delay time on the ordinate axis. The DG MOSFET used to obtain the data provided in FIG. 2 is approximately of the 100 nm technology node and has a minimum channel length defined as about 50 nm. As illustrated in FIG. 2, the performance of a DG MOSFET of circuit operating in a sub-threshold mode is improved for devices having channel lengths, L_{ch}, longer than the minimum channel length when the leakage current, I_{off}, of the devices of the circuit are matched. Performance of the DG MOSFET is improved by increasing the channel length, L_{ch}, because of the effect of two factors, C_{g} and Iₒₙ. For example, referring to FIG. 3, a graph 40 illustrating a change in gate-to-source voltage, V_{gs}, versus a change in gate capacitance, C_{g}, of a DG MOSFET having different channel lengths, L_{ch}, is shown. The graph 40 includes the gate-to-source voltage on the abscissa axis versus the gate capacitance on the ordinate axis. As shown in FIG. 3, the gate capacitance, C_{g}, is nearly constant regardless of the channel length, L_{ch}, in the DG MOSFET sub-threshold device because the main components of the gate capacitance, C_{g}, for sub-threshold DG MOSFET devices are the gate overlap capacitance and fringing gate capacitance, which are not dependent on the channel length, L_{ch}. It should be noted that the intrinsic gate capacitance, C_{g}, of DG MOSFETs is accordingly negligible as it relates to changes in channel lengths, L_{ch}. Therefore, dependence of the time delay, t_{d}, on channel length, L_{ch}, in DG MOSFET operating in the sub-threshold mode is mainly a function of the operating current, Iₒₙ.

Referring now to FIG. 4, a graph 50 illustrating change in operating current, Iₒₙ, and change in the sub-threshold slope, S, of a DG MOSFET device versus a change in the channel length of the DG MOSFET device is shown. The graph 40 includes the operating current on a left ordinate axis, the sub-threshold slope on a right ordinate axis, and the channel length on the abscissa axis. The sub-threshold slope, S, is defined as the ratio of a change in the drain current to a change in the gate voltage (i.e., S=(d(log₁₀ I_{d})/dV_{g})⁻¹) of the DG MOSFET device. With a relatively small increase in the gate charge, Q_{g}, longer channel semiconductor devices have larger operating current, Iₒₙ, in the sub-threshold region under the same leakage current, I_{off}, condition as shown in FIG. 4. The increased operating current of the longer channel semiconductor device is due to the smaller sub-threshold slope, S. It should be noted that the operating current, Iₒₙ, in the sub-threshold region is a function of the sub-threshold slope, S, only if the leakage current, I_{off}, is fixed. The leakage current, I_{off}, of each device was matched with different channel lengths, L_{ch}, by adjusting the gate-to-metal workfunctions. As shown in FIG. 4, the sub-threshold slope, S, of shorter channel semiconductor devices is larger than the sub-threshold slope, S, of the longer channel devices due to the aforementioned short channel effects.

FIG. 4 also shows the dependency of the operating current, Iₒₙ, to the sub-threshold slope, S, in the sub-threshold region of operation. Because the operating current, Iₒₙ, does not increase with the channel length, L_{ch}, once the sub-threshold slope, S, approaches an ideal limit (see FIG. 4), there is a desirable channel length, L_{ch}, for a minimum time delay, t_{d}, as shown in FIG. 2. That is, a channel length, L_{ch}, for a sub-threshold operation semiconductor device may be initially selected based on the sub-threshold slope, S, based on FIG. 4 (i.e., selected such that the sub-threshold slope for the selected channel length is of a low value). The initially selected channel length, L_{ch}, may then be increased to a greater length, based on FIG. 2, to achieve an improved time delay, t_{d}. Accordingly, a desirable channel length for sub-threshold operation may be defined, in some embodiments, as the minimum channel length which has an ideal sub-threshold slope.

Based on the analysis of the time delay, t_{d}, and sensitivity to process variations, transistors or other semiconductor devices having channel lengths, L_{ch}, longer than the minimum channel lengths defined for the particular technology node may be used for reliable sub-threshold operations with minimal loss of performance (e.g., delay time performance) under the same leakage current, I_{off}, condition. For example, in some embodiments, the desirable channel length, L_{ch}, of a transistor may be determined based on the time delay, t_{d}, defined for each technology node and/or application. The channel length may be increased until a lower time delay, t_{d}, (e.g., a minimum time delay) is achieved. For example, referring back to FIG. 2, the exemplary DG MOSFET device is approximately of the 100 nm technology node and has a standard minimum channel length of about 50 nm. However, as shown in FIG. 2, a DG MOSFET device having the channel length, L_{ch}, having the minimum time delay, t_{d}, has a channel length, L_{ch}, of approximately 100 nm, which is a greater than the defined minimum channel length of 50 nm for the 100 nm technology node of the device.

As discussed above, because the channel resistance of a DG MOSFET configured for sub-threshold operation is high compared to conventional devices used for sub-threshold operation, the DG MOSFET devices for sub-threshold operation may have reduced source/drain structures compared to the conventional sub-threshold devices. Referring now to FIG. 5, a graph 60 illustrating a change in the drain-to-source current, I_{ds}, versus a change in the supply voltage, V_{dd}, of a DG MOSFET having different source resistances, Rₛ, is shown. The graph 50 includes the drain-to-source current on the ordinate axis and the supply voltage on the abscissa axis. In typical DG MOSFET devices, the source and drain region structures are raised to reduce the source/drain resistance of the DG MOSFETs (see FIG. 6). Conventional DG MOSFETs are processed in this way because the source/drain resistance is comparable to the channel resistance in such designs. However, the channel resistance of a DG MOSFET device operating in the sub-threshold region is higher than that of a conventional CMOS logic devices operating in the strong inversion region. Accordingly, the source/drain resistance of a DG MOSFET device operating in the sub-threshold region may be smaller (e.g., much smaller) than the channel resistance of the device even though the height of the source and drain regions are not raised. As illustrated in FIG. 5, the operating current in the sub-threshold region is not substantially affected by the source/drain resistance. Conversely, as FIG. 5 shows, strong inversion current varies noticeably depending on source/drain resistance. Accordingly, raised source/drain structures are not required for sub-threshold operations.

Referring now to FIG. 7, a DG MOSFET device 70 for sub-threshold operation is fabricated on a substrate 72. The substrate 72 may be, for example, a silicon substrate. The device 70 includes a front gate 74, a back gate 76, a source region 78, and a drain region 80. The gates 74, 76 and regions 78, 80 define a channel region 82 therebetween. The front gate 74 is formed over a gate oxide 84 and the back gate 76 is formed over a gate oxide 86. The source region 78 and drain region 80 are doped regions defined in the substrate 72 and may be positively or negatively doped depending on the desired type of device. The substrate 72 includes a top surface 88 and a bottom surface 90. The device 70 is designed such that the source region 78 does not extend away from the top surface 88 of the substrate 72 and the drain region 80 does not extend away from the bottom surface 99 of the substrate 72. That is, the front gate terminal 74 is raised to a height greater than the height of the source region 78 and the drain region 80. Similarly, the back gate terminal 76 is raised to a height greater than the height of the source region 78 and the drain region 80. It should be appreciated that the DG MOSFET device 70 is only one example of a DG MOSFET for sub-threshold operation having reduced source and drain regions and that, in other application, other configurations of DG MOSFET devices may be used that include reduced source and drain regions compared to other typical devices used in sub-threshold applications.

While the disclosure has been illustrated and described in detail in the drawings and foregoing description, such an illustration and description is to be considered as exemplary and not restrictive in character, it being understood that only illustrative embodiments have been shown and described and that all changes and modifications that come within the spirit of the disclosure are desired to be protected.

There are a plurality of advantages of the present disclosure arising from the various features of the device described herein. It will be noted that alternative embodiments of the device of the present disclosure may not include all of the features described yet still benefit from at least some of the advantages of such features. Those of ordinary skill in the art may readily devise their own implementations of the device that incorporate one or more of the features of the present invention and fall within the spirit and scope of the present disclosure as defined by the appended claims.

1. A semiconductor device fabricated according to a predetermined technology node process wherein the predetermined technology node process defines a minimum channel length, the semiconductor device comprising:
a source region;
a drain region; and
a channel region defined between the source and drain regions, the channel region having a length greater than minimum channel length.

2. The semiconductor device of claim 1, wherein the length of the channel region is determined based on a minimum time delay associated with the length of the channel region.

3. The semiconductor device of claim 1, wherein the length of the channel region is determined based on a minimum sub-threshold slope associated with the length of the channel region.

4. The semiconductor device of claim 1, further comprising a first gate region established over the channel region, wherein the first gate region is raised a height above the source and drain regions.

5. The semiconductor device of claim 4, further comprising a second gate region established over the channel region, wherein the second gate region is raised a height above the source and drain regions.

6. The semiconductor device of claim 1, wherein the source region and the drain region are defined in a substrate, a top surface of the source region and a top surface of the drain region being substantially coplanar with a top surface of the substrate.

7. The semiconductor device of claim 1, wherein the source, drain, and channel regions form portions of a metal-oxide semiconductor field effect transistor.

8. The semiconductor device of claim 7, wherein the metal-oxide semiconductor field effect transistor is a double gate metal-oxide semiconductor field effect transistor

9. A double gate metal-oxide field effect transistor fabricated according to a predetermined technology node process wherein the predetermined technology node process defines a minimum channel length, the double gate metal-oxide field effect transistor comprising a channel length greater than the minimum channel length.

10. The double gate metal-oxide field effect transistor of claim 6, wherein the channel length is determined based on a minimum time delay associated with the channel length.

11. The double gate metal-oxide field effect transistor of claim 6, wherein the channel length is determined based on a minimum sub-threshold slope associated with the channel length.

12. An electrical circuit comprising:
a semiconductor device fabricated according to a predetermined technology node process wherein the predetermined technology node process defines a minimum channel length, the semiconductor device having (i) a gate terminal, (ii) a source terminal, (iii) a drain terminal, and (iv) a channel defined between the gate terminal, source terminal, and drain terminal, the channel having a length greater than the minimum channel length; and
a supply voltage applied to the source terminal of the semiconductor, the supply voltage being less than a threshold voltage of the semiconductor device.

13. The electrical circuit of claim 12, wherein length of the channel is determined based on a minimum time delay associated with the length of the channel.

14. The electrical circuit of claim 12, wherein the length of the channel is determined based on a minimum sub-threshold slope associated with the length of the channel.

15. A method of fabricating a device on a substrate having a top surface according to a predetermined technology node process wherein the predetermined technology node process defines a minimum channel length, the method comprising:
establishing a source region in the substrate;
establishing a drain region in the substrate;
establishing a channel region between the source region and the drain region, the channel region having a channel length greater than the minimum channel length.

16. The method of claim 15, wherein the channel length is determined based on a minimum time delay associated with the channel length.

17. The method of claim 15, wherein the channel length is determined based on a minimum threshold slope associated with the channel length.

18. The method of claim 15, wherein the source region comprises a top surface substantially coplanar with the top surface of the substrate and the drain region comprises a top surface substantially coplanar with the top surface of the substrate.

19. The method of claim 15, further comprising establishing a first gate region over the channel region, the first gate region having a height greater than a height of the source region and the drain region.

20. The method of claim 19, further comprising establishing a second gate region over the channel region, the second gate region having a height greater than the height of the source region and the drain region.
